(19) United States
(12) Patent Application Publication
(10) Pub. No.: US 2015/0162493 A1
(43) Pub. Date: Jun. 11, 2015

(54) SEMICONDUCTOR LIGHT EMITTING DEVICE

(71) Applicant: Intellectual Discovery Co., Ltd., Seoul (KR)

(72) Inventor: Do-Yeol Ahn, Seoul (KR)

(73) Assignee: Intellectual Discovery Co., Ltd., Seoul (KR)

(21) Appl. No.: 14/411,805

(22) PCT Filed: Jul. 1, 2013
(86) PCT No.: PCT/KR2013/005831

§ 371 Date: Dec. 29, 2014

(30) Foreign Application Priority Data
Jun. 29, 2012 (KR) 10-2012-0070835

(51) Int. Cl. H01L 33/06; H01L 33/30; H01L 33/32

(52) U.S. Cl. CPC H01L 33/06; H01L 33/32; H01L 33/30

(57) ABSTRACT

A semiconductor light emitting device capable of enhancing light emitting efficiency is disclosed. The semiconductor light emitting device includes an n-type semiconductor layer, a quantum well layer, a barrier layer and a p-type semiconductor layer. The quantum well layer is formed on the n-type semiconductor layer. The barrier layer is formed on the quantum well layer. The p-type semiconductor layer is formed on the barrier layer. The barrier layer includes at least one p-type delta doping layer.

### TECHNICAL FIELD

The present invention relates to a light emitting device, and more particularly to a semiconductor light emitting device.

### BACKGROUND ART

A semiconductor light emitting device such as an LED is eco-friendly, capable of driving with low voltage and can be embodied with small size. After the semiconductor light emitting device was invented, the semiconductor light emitting device is widely used in various fields to the above-mentioned merits. Especially, after the semiconductor light emitting device with III-V nitride semiconductor quantum well was invented, white light could be realized so that the semiconductor light emitting device increases application scope such as a backlight of LCT TV, a lighting apparatus, etc.

On the other hand, there exists continuous efforts to raise efficiency of the semiconductor light emitting device with III-V nitride semiconductor quantum well. For example, an electron blocking layer (EBL) is induced.

FIG. 1 is a diagram showing a band structure of a conventional semiconductor light emitting device.

Referring to FIG. 1, the electron blocking layer prevents electrons that has passed through quantum well from being transferred to p-type region.

A conventional AlGaN electron blocking layer is shown. As shown in FIG. 1, the electron blocking layer prevents electrons being transferred along a path ‘a’ to block the electrons, but the electron blocking layer operates as a potential barrier Vb regarding to holes from a p-type semiconductor layer along a path ‘b’. Therefore, density of holes in the quantum well becomes lower so that light emitting efficiency becomes lowered. Further, an increase of effective mass of holes and internal fields induced by piezo and spontaneous polarization become factors that deteriorates effectiveness of hole injection.

### DISCLOSURE

### Technical Problem

Therefore, the technical problem of the present invention is to provide a semiconductor light emitting device capable of improving light emitting efficiency.

### Technical Solution

A semiconductor light emitting device according to an embodiment of the present invention includes an n-type semiconductor layer, a quantum well layer, a barrier layer and a p-type semiconductor layer. The quantum well layer is formed on the n-type semiconductor layer.

The barrier layer is formed on the quantum well layer. The p-type semiconductor layer is formed on the barrier layer. The barrier layer includes at least one p-type delta doping layer.

The p-type delta doping layer may be formed such that the p-type delta doping layer is adjacent to the quantum well layer.

The n-type semiconductor layer, the quantum well layer, the barrier layer and the p-type semiconductor layer may include at least one of GaN, InGaN, AlInGaN and AlGaN.

The semiconductor light emitting device may further include at least one electron blocking layer formed between the barrier layer and the p-type semiconductor layer.

In this case, the p-type delta doping layer may be spaced apart from the electron blocking layer by at least 10 nm.

Further, the electron blocking layer may include at least one p-type delta doping layer.

Furthermore, the electron blocking layer comprises at least one of AlGaNSb and AlGaNAs.

In this case, a composition ratio of aluminum (Al) in AlGaNSb and AlGaNAs may in a range of 0.3 to 0.8, and a composition ratio of antimony (Sb) and arsenic (As) in AlGaNSb and AlGaNAs, respectively may be in a range of 0.01 to 0.1.

A semiconductor light emitting device according to another embodiment may include a substrate, an n-type semiconductor layer, a quantum well layer, a barrier layer, an electron blocking layer and a p-type semiconductor layer. The n-type semiconductor layer is formed on the substrate. The quantum well layer is formed on the n-type semiconductor layer. The barrier layer is formed on the quantum well layer. Then electron blocking layer is formed on the barrier layer. The p-type semiconductor layer is formed on the electron blocking layer. The electron blocking layer includes at least one p-type delta doping layer.

The n-type semiconductor layer, the quantum well layer, the barrier layer and the p-type semiconductor layer may include at least one of GaN, InGaN, AlInGaN and AlGaN.

The barrier layer may include at least one of p-type delta doping layer.

The p-type delta doping layer in the barrier layer may be formed such that the p-type delta doping layer is adjacent to the quantum well layer.

The p-type delta doping layer in the barrier layer may be spaced apart from the electron blocking layer by at least 10 nm.

The electron blocking layer may include at least one of AlGaNSb and AlGaNAs.

In this case, a composition ratio of aluminum (Al) in AlGaNSb and AlGaNAs may be in a range of 0.3 to 0.8, and a composition ratio of antimony (Sb) and arsenic (As) in A1GaNSb and AlGaNAs, respectively may be in a range of 0.01 to 0.1.

### Advantageous Effects

When the barrier layer includes the p-type delta-doping layer as the semiconductor light emitting device according to the present invention, internal field of active layer, which is induced by piezo effect and spontaneous polarization, can be reduced to enhance light emitting efficiency.

When the barrier layer includes the p-type delta doping layer, electrons are effectively blocked while effectively transmitting holes. The energy level of the p-type delta doping layer raises possibility of tunneling of holes provided from p-type electrode to enhance light emitting efficiency.

When the electron blocking layer includes at least one of AlGaNSb and AlGaNAs, wall is lowered regarding to holes and while the wall blocking the electrons, so that increasing holes to improve enhance internal quantum efficiency to enhance light emitting efficiency.

Further, when the electron blocking layer of above includes p-type delta doping layer, the light emitting efficiency may be further enhanced.

Additionally, when the p-type delta doping layer in the barrier layer is adjacent to the active layer, the p-type delta doping layer is spaced apart from the electron blocking layer in maximum so that the electrons and holes are spaced apart in maximum to reduce Auger recombination possibility effectively.

### DESCRIPTION OF DRAWINGS

FIG. 1 is a diagram showing a band structure of a conventional semiconductor light emitting device.

FIG. 2 is a diagram showing a band structure of a semiconductor light emitting device according to an embodiment of the present invention. FIG. 3 is a diagram showing a band structure of a semiconductor light emitting device according to another embodiment of the present invention.

FIG. 4 is a diagram showing a band structure of a semiconductor light emitting device according to still another embodiment of the present invention.

FIG. 5 is a diagram showing a band structure of a semiconductor light emitting device according to still another embodiment of the present invention.

### MODE FOR INVENTION

The present invention may be embodied in many different forms, and the present invention is described more fully hereinafter with reference to the accompanying drawings. However, the present invention should not be construed as limited to the example embodiments set forth herein. Rather, these example embodiments are provided so that this disclosure will be thorough and complete, and will fully convey the scope of the present invention to those skilled in the art.

It will be understood that, although the terms first, second etc. may be used herein to describe various elements, these elements should not be limited by these terms. These terms are only used to distinguish one element from another element. Thus, a first element could be termed a second element and a second element could be termed a first element without departing from the teachings of the present invention.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In the present invention, “formed on a film (or layer)” means not only “formed on a film (or layer) contacting the film (or the layer)” but also “some other film (or layer) may be interposed therebetween”, and “directly formed on a film (or layer)” means “no other film (or layer) is interposed therebetween”.

Unless otherwise defined, all terms (including technical and scientific terms) used herein have the same meaning as commonly understood by one of ordinary skill in the art to which this invention belongs.

It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, with reference to the drawings, preferred embodiments of the present invention will be described in detail.

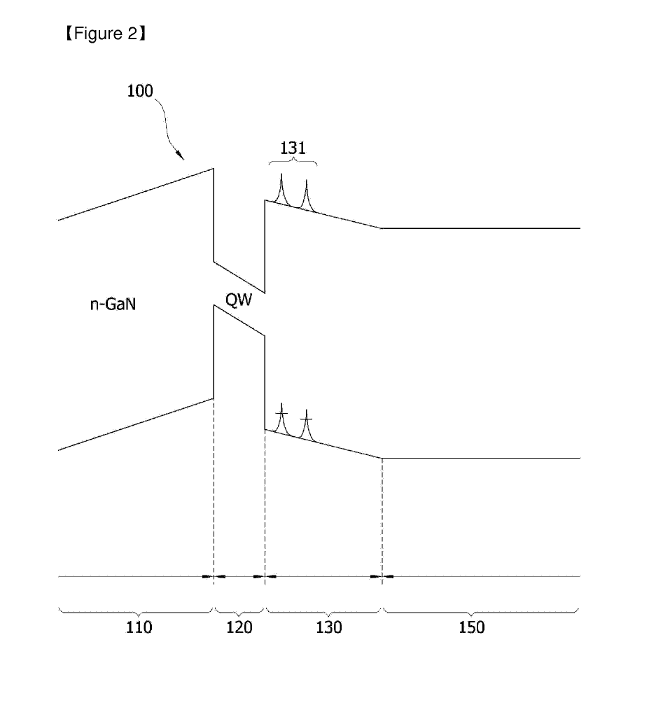

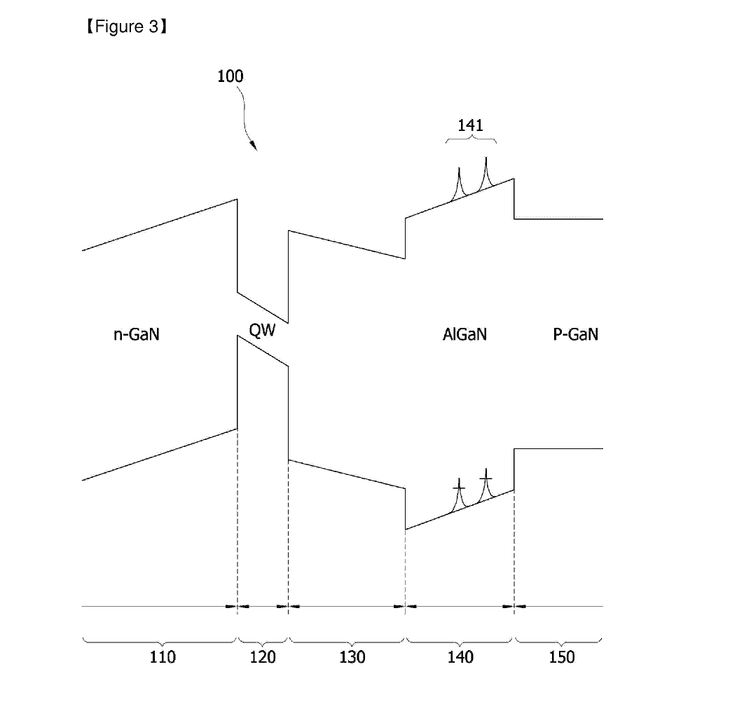

FIG. 2 is a diagram showing a band structure of a semiconductor light emitting device according to an embodiment of the present invention.

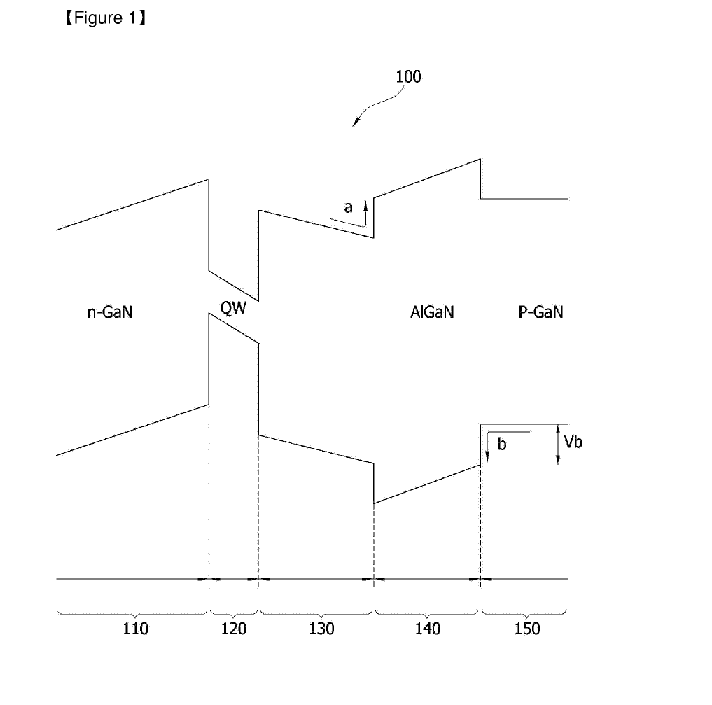

Referring to FIG. 2, a semiconductor light emitting device 100 according to an embodiment of the present invention includes an n-type semiconductor layer 110, a quantum well layer 120, a barrier layer 130 and a p-type semiconductor layer 150. Not shown in FIG. 2, the semiconductor light emitting device 100 may further include an electron blocking layer 140 shown in FIG. 1.

The n-type semiconductor layer 110 may be formed on a substrate (not shown). For example, a sapphire substrate may be used as the substrate. The quantum well layer 120 is formed on the n-type semiconductor layer 110. The barrier layer 130 is formed on the quantum well layer 120. The p-type semiconductor layer 150 is formed on the barrier layer 130. The n-type semiconductor layer 110, the quantum well layer 120, the barrier layer 130 and the p-type semiconductor layer 150 may include at least one of GaN, InGaN, AlInGaN and AlGaN, respectively. In general, a band gap becomes smaller when amount of Indium (In) increases, and greater when amount of aluminum (Al) increases. Therefore, for example, the quantum well layer 120 includes InGaN, and the barrier layer 130 includes AlGaN in the present invention.

On the other hand, the barrier layer 130 includes at least one p-type delta doping layer 131. The p-type delta doping layer 131 may be formed such that the p-type delta doping layer 131 is adjacent to the quantum well layer 120. When the barrier layer 130 is adjacent to the quantum well layer 120, the height of barrier of the quantum well layer 120 increases to lower probability of transferring of electrons from the quantum well layer 120 to the barrier layer 130, and the p-type delta doping layer 131 reduces internal field induced by piezo effect and spontaneous polarization so that internal quantum efficiency is enhanced.

FIG. 3 is a diagram showing a band structure of a semiconductor light emitting device according to another embodiment of the present invention.

Referring to FIG. 3, a semiconductor light emitting device 100 according to another embodiment of the present invention includes an n-type semiconductor layer 110, a quantum well layer 120, a barrier layer 130, an electron blocking layer 140 and a p-type semiconductor layer 150. The n-type semiconductor layer 110 may be formed on a substrate (not shown). For example, a sapphire substrate may be used as the substrate. The quantum well layer 120 is formed on the n-type semiconductor layer 110. The barrier layer 130 is formed on the quantum well layer 120. The electron blocking layer 140 is formed on the barrier layer 130. The p-type semiconductor layer 150 is formed on the electron blocking layer 140. The n-type semiconductor layer 110, the quantum well layer 120, the barrier layer 130, the electron blocking layer 140 and the p-type semiconductor layer 150 may include at least one of GaN, InGaN, AlInGaN and AlGaN, respectively. In general, a band gap becomes smaller when amount of Indium (In) increases, and greater when amount of aluminum (Al) increases. Therefore, for example, the quantum well layer 120 includes InGaN, and the barrier layer 130 includes AlGaN in the present invention.

On the other hand, the electron blocking layer 140 includes at least one p-type delta doping layer 141. When the electron blocking layer 140 includes at least one p-type delta doping layer 141, electrons are effectively blocked while holes are effectively transmitted. That is, energy level of holes in the p-type delta doping layer 141 increases probability of tunneling of holes from the p-type electrode to enhance internal quantum efficiency.

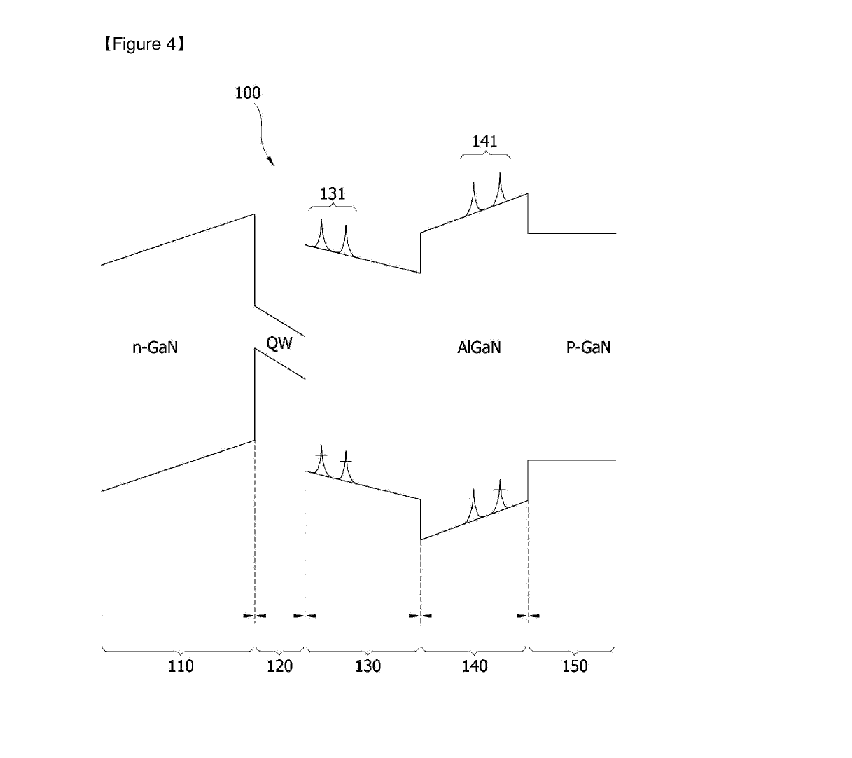

FIG. 4 is a diagram showing a band structure of a semiconductor light emitting device according to still another embodiment of the present invention. The semiconductor light emitting device in FIG. 4 has additionally a p-type delta doping layer 131 in FIG. 2 in comparison with the semiconductor light emitting device in FIG. 3. However, when the p-type delta doping layer 131 is formed at the barrier layer 130, and the p-type delta doping layer 141 is formed at the electron blocking layer 140, there exist additional effects besides above mentioned effects. Repetitive explanation will be omitted.

Referring to FIG. 4, a semiconductor light emitting device 100 according to still another embodiment of the present invention includes an n-type semiconductor layer 110, a quantum well layer 120, a barrier layer 130, an electron blocking layer 140 and a p-type semiconductor layer 150. The barrier layer 130 includes at least one p-type delta doping layer 131. The p-type delta doping layer 131 may be formed such that the p-type delta doping layer 131 is adjacent to the quantum well layer 120. The p-type delta doping layer 131 in the barrier layer 130 may be spaced apart from the electron blocking layer by at least 10 nm. Further, the electron blocking layer 140 includes at least one p-type delta doping layer 141.

The potential formed by delta doping may be expressed as following Expression 1 [D. Ahn, Phys. Rev. 48, 7981 (1993)].

V(z)=e²Pₛ/2ε|z| Expression 1

In the above Expression 1, is surface charge density of the delta doping layer. Energy level of hole may be obtained by Schroedinger equation as shown in following Expression 2.

$$- \frac{{ℏ}^{2}}{2 m} \frac{{d}^{2}}{d {z}^{2}} φ ( z ) + {eF}_{s} \vert z \vert φ ( z ) = Eφ ( z ) \qquad Expression 2$$

In the above Expression 2, Fₛ=ePₛ/2ε.

The structure capable of separating maximum distribution of electrons and holes for reducing Auger recombination is as shown in FIG. 4.

The p-type delta doping layer in the barrier layer 130 offsets internal field so that the p-type delta doping layer in the barrier layer 130 is disposed near the quantum well layer 120 but spaced apart from the electron blocking layer 140 (by at least 10 nm). Due to the electron blocking layer 140, maximum density of electron is generated just before the electron blocking layer in the p-type semiconductor layer 150. Meanwhile, due to the p-type delta doping layer 131 in the barrier layer 130, maximum density of holes is generated at the p-type delta doping layer formed just next a last barrier of the quantum well layer 120 and at the p-type delta doping layer 141 in the electron blocking layer 140 to effectively reduce Auger recombination possibility.

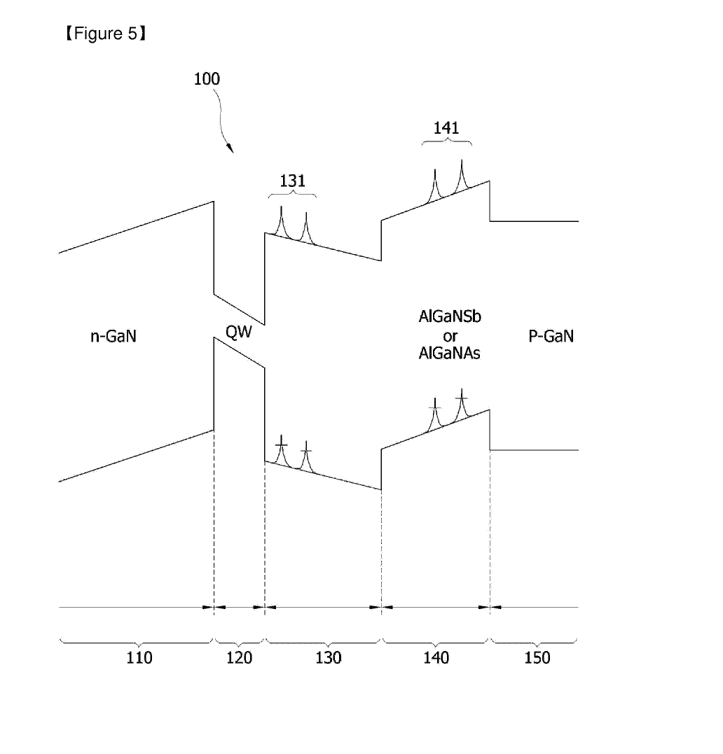

FIG. 5 is a diagram showing a band structure of a semiconductor light emitting device according to still another embodiment of the present invention. The semiconductor light emitting device according to the present embodiment is substantially same as the semiconductor light emitting device in FIG. 4 except for the electron blocking layer. Therefore, same reference numerals are applied to same or similar elements, and repetitive explanation will be omitted. Further, according to the present embodiment, the electron blocking layer of the previous embodiment in FIG. 4 is changed, but same change may be applied to the previous embodiment in FIG. 3.

Referring to FIG. 5, the semiconductor light emitting device 100 according to the present embodiment includes an n-type semiconductor layer 110, a quantum well layer 120, a barrier layer 130, an electron blocking layer 140 and a p-type semiconductor layer 150. The barrier layer 130 may include a p-type delta doping layer 131 and the electron blocking layer may include also a p-type delta doping layer 141.

The electron blocking layer 140 may include at least one of AlGaNSb and AlGaNAs. When a small amount of antimony (Sb) or arsenic (As) is added to the electron blocking layer 140, the blocking layer 140 blocks electrons but transmits holes as shown in FIG. 5. In AlGaNSb and AlGaNAs, a composition ratio of aluminum (Al) may be in a range of 0.3 to 0.8, and a composition ratio of antimony (Sb) and arsenic (As) may be in a range of 0.01 to 0.1. In that range, a best efficiency may be obtained.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

1. A semiconductor light emitting device comprising:
an n-type semiconductor layer;
a quantum well layer formed on the n-type semiconductor layer;
a barrier layer formed on the quantum well layer; and
a p-type semiconductor layer formed on the barrier layer,
wherein the barrier layer includes at least one p-type delta doping layer.

2. The semiconductor light emitting device of claim 1, wherein the p-type delta doping layer is formed such that the p-type delta doping layer is adjacent to the quantum well layer.

3. The semiconductor light emitting device of claim 1, wherein the n-type semiconductor layer, the quantum well layer, the barrier layer and the p-type semiconductor layer comprises at least one of GaN, InGaN, AlInGaN and AlGaN.

4. The semiconductor light emitting device of claim 1, further comprising at least one electron blocking layer formed between the barrier layer and the p-type semiconductor layer.

5. The semiconductor light emitting device of claim 4, wherein the p-type delta doping layer is spaced apart from the electron blocking layer by at least 10 nm.

6. The semiconductor light emitting device of claim 4, wherein the electron blocking layer comprises at least one p-type delta doping layer.

7. The semiconductor light emitting device of claim 4, wherein the electron blocking layer comprises at least one of AlGaNSb and AlGaNAs.

8. The semiconductor light emitting device of claim 7, wherein a composition ratio of aluminum (Al) in AlGaNSb and AlGaNAs is in a range of 0.3 to 0.8, and a composition ratio of antimony (Sb) and arsenic (As) in AGaNSb and AlGaNAs, respectively is in a range of 0.01 to 0.1.

9. A semiconductor light emitting device comprising:
a substrate;
an n-type semiconductor layer formed on the substrate;
a quantum well layer formed on the n-type semiconductor layer;
a barrier layer formed on the quantum well layer;
an electron blocking layer formed on the barrier layer; and
a p-type semiconductor layer formed on the electron blocking layer,
wherein the electron blocking layer includes at least one p-type delta doping layer.

10. The semiconductor light emitting device of claim 9, wherein the n-type semiconductor layer, the quantum well layer, the barrier layer and the p-type semiconductor layer comprises at least one of GaN, InGaN, AlInGaN and AlGaN.

11. The semiconductor light emitting device of claim 9, wherein the barrier layer comprises at least one of p-type delta doping layer.

12. The semiconductor light emitting device of claim 11, wherein the p-type delta doping layer in the barrier layer is formed such that the p-type delta doping layer is adjacent to the quantum well layer.

13. The semiconductor light emitting device of claim 11, wherein the p-type delta doping layer in the barrier layer is spaced apart from the electron blocking layer by at least 10 nm.

14. The semiconductor light emitting device of claim 9, wherein the electron blocking layer comprises at least one of AlGaNSb and AlGaNAs.

15. The semiconductor light emitting device of claim 14, wherein a composition ratio of aluminum (Al) in AlGaNSb and AlGaNAs is in a range of 0.3 to 0.8, and a composition ratio of antimony (Sb) and arsenic (As) in AlGaNSb and AlGaNAs, respectively is in a range of 0.01 to 0.1.
